(19) United States
(12) Patent Application Publication
(10) Pub. No.: US 2026/0190588 A1
(43) Pub. Date: Jul. 2, 2026

(54) MODULE

(71) Applicant: HYUNDAI MOBIS CO., LTD., Seoul (KR)

(72) Inventors: Eun Bi KWON, Yongin-si (KR); Seok Ho JEONG, Yongin-si (KR)

(73) Assignee: HYUNDAI MOBIS CO., LTD., Seoul (KR)

(21) Appl. No.: 19/290,003

(22) Filed: Aug. 4, 2025

(30) Foreign Application Priority Data
Dec. 31, 2024 (KR) 10-2024-0202984

(51) Int. Cl. H10H 29/855; C08L 83/04; H10H 29/854

(52) U.S. Cl. CPC H10H 29/855; C08L 83/04; H10H 29/854; C08L 2203/14; C08L 2203/206

(57) ABSTRACT

The present invention relates to a module, which includes a circuit board; a light-emitting device placed on the circuit board; and a diffusion layer placed on the light-emitting device, wherein the diffusion layer is formed of a composition for forming a diffusion layer, wherein the composition includes a base resin including a siloxane-based compound; and a (meth)acrylic diffusion agent, and wherein a content of the (meth)acrylic diffusion agent based on a total weight of the composition is 1.0 to 10.0 wt %.

### CROSS-REFERENCE TO RELATED APPLICATION

This application claims priority to and the benefit under 35 USC § 119 of Korean Patent Application No. 10-2024-0202984, filed on Dec. 31, 2024, in the Korean Intellectual Property Office, the disclosure of which is incorporated herein by reference in its entirety.

### BACKGROUND

### 1. Field of the Invention

The present invention relates to a module.

### 2. Discussion of Related Art

A light-emitting device consumes less power, have a longer lifespan and a faster response time, and is more stable and environmentally friendly compared to conventional light sources such as fluorescent and incandescent lamps. For the reasons mentioned above, a light-emitting device is being used as a light source for a display device, lighting device or vehicle.

Among light-emitting devices, a top view-type light-emitting device has a beam angle of 120 degrees, and has a hot spot problem where light is concentrated around the top surface. In addition, to solve this problem, a surface light source was implemented by applying separate optical components such as an air gap and inner lens to the light-emitting device. Here, the inner lens may be a corrosion-treated inner lens or an optic inner lens to scatter direct/indirect light.

However, even with this optical system, dark areas are still present and it is difficult to achieve high luminance that can satisfy North American regulations.

### SUMMARY

In one general aspect, the module includes: a circuit board; a light-emitting device placed on the circuit board; and a diffusion layer placed on the light-emitting device, wherein the diffusion layer is formed of a composition for forming a diffusion layer, wherein the composition includes a base resin including a siloxane-based compound; and a (meth)acrylic diffusion agent, and wherein a content of the (meth)acrylic diffusion agent based on a total weight of the composition is 1.0 to 10.0 wt %.

The diffusion layer may be a single layer covering the light-emitting device.

The light-emitting device may have a beam angle of 120° or more when emitting light from a top surface of the light-emitting device.

The light-emitting device may have a beam angle of 140° or more when emitting light from a side surface of the light-emitting device.

The siloxane-based compound may include a substituent represented by Chemical Formula 1:

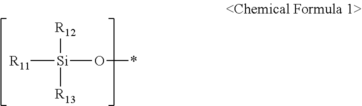

wherein, in Chemical Formula 1, R₁₁ to R₁₃ are each independently selected from the group consisting of hydrogen, a C₁ to C₂₀ alkyl group, and a C₂ to C₂₀ alkenyl group, and at least one of R₁₁ to R₁₃ is a C₂ to C₂₀ alkenyl group.

The siloxane-based compound may include a siloxane-based compound represented by Chemical Formula 1-1 below:

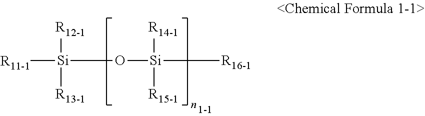

wherein, in Chemical Formula 1-1, R₁₁₋₁ to R₁₃₋₁ are each independently selected from the group consisting of hydrogen, a C₁ to C₂₀ alkyl group, and a C₂ to C₂₀ alkenyl group, and at least one of R₁₁₋₁ to R₁₃₋₁ is a C₂ to C₂₀ alkenyl group, R₁₄₋₁ and R₁₅₋₁ are each independently selected from the group consisting of hydrogen and a C₁ to C₂₀ alkyl group, R₁₆₋₁ is selected from the group consisting of hydrogen, a C₁ to C₂₀ alkyl group, and a C₂ to C₂₀ alkenyl group, and n₁₋₁ is 100 to 500.

The siloxane-based compound may include a siloxane-based compound represented by Chemical Formula 1-2 below:

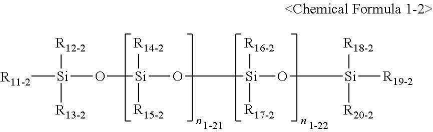

wherein, in Chemical Formula 1-2, R₁₁₋₂ to R₁₃₋₂ are each independently selected from the group consisting of hydrogen, C₁ to C₂₀ alkyl group, and a C₂ to C₂₀ alkenyl group, and at least one of R₁₁₋₂ to R₁₃₋₂ is a C₂ to C₂₀ alkenyl group, R₁₄₋₂ to R₁₇₋₂ are each independently selected from the group consisting of hydrogen, a C₁ to C₂₀ alkyl group, and a C₂ to C₂₀ alkenyl group, and at least one of R₁₄₋₂ to R₁₇₋₂ is a C₂ to C₂₀ alkenyl group, R₁₈₋₂ to R₂₀₋₂ are each independently selected from the group consisting of hydrogen, a C₁ to C₂₀ alkyl group, and a C₂ to C₂₀ alkenyl group, and
n₁₋₂₁ and n₁₋₂₂ are 100 to 500.

The siloxane-based compound may include a siloxane-based compound represented by Chemical Formula 1-3 below:

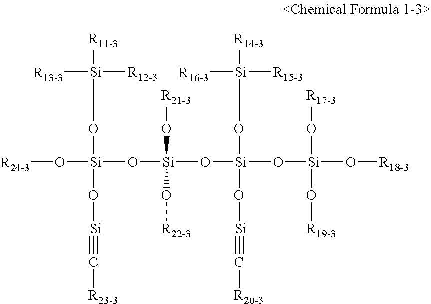

wherein, in Chemical Formula 1-3, R₁₁₋₃ to R₁₃₋₃ are each independently selected from the group consisting of hydrogen, a C₁ to C₂₀ alkyl group, and a C₂ to C₂₀ alkenyl group, and at least one of R₁₁₋₃ to R₁₃₋₃ is a C₂ to C₂₀ alkenyl group, and R₁₄₋₃ to R₂₄₋₃ are each independently selected from the group consisting of hydrogen, a C₁ to C₂₀ alkyl group, and a C₂ to C₂₀ alkenyl group.

The siloxane-based compound represented by Chemical Formula 1-1 may be a siloxane-based compound represented by Chemical Formula 1-1-1 below:

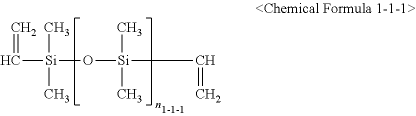

wherein, in Chemical Formula 1-1-1, n₁₋₁₋₁ is 100 to 500.

The siloxane-based compound represented by Chemical Formula 1-2 may be a siloxane-based compound represented by Chemical Formula 1-2-1 below:

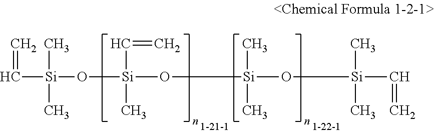

wherein, in Chemical Formula 1-2-1, n₁₋₂₁₋₁ and n₁₋₂₂₋₁ are each independently 100 to 500.

The siloxane-based compound represented by Chemical Formula 1-3 may be a siloxane-based compound represented by Chemical Formula 1-3-1 below:

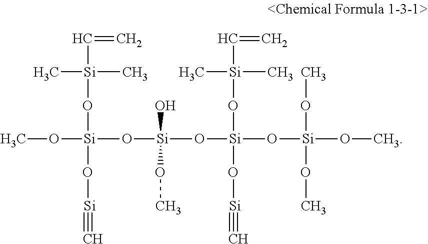

The base resin may include at least two or more siloxane-based compound selected from the group consisting of a siloxane-based compound represented by Chemical Formula 1-1 below, a siloxane-based compound represented by Chemical Formula 1-2 below, and a siloxane-based compound represented by Chemical Formula 1-3 below:

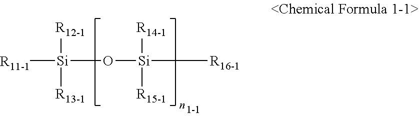

wherein, in Chemical Formula 1-1, R₁₁₋₁ to R₁₃₋₁ are each independently selected from the group consisting of hydrogen, a C₁ to C₂₀ alkyl group, and a C₂ to C₂₀ alkenyl group, and at least one of R₁₁₋₁ to R₁₃₋₁ is a C₂ to C₂₀ alkenyl group, R₁₄₋₁ and R₁₅₋₁ are each independently selected from the group consisting of hydrogen and a C₁ to C₂₀ alkyl group, R₁₆₋₁ is hydrogen, a C₁ to C₂₀ alkyl group, or a C₂ to C₂₀ alkenyl group, and n₁₋₁ is 100 to 500;

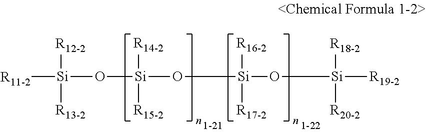

wherein, in Chemical Formula 1-2, R₁₁₋₂ to R₁₃₋₂ are each independently selected from the group consisting of hydrogen, C₁ to C₂₀ alkyl group, and a C₂ to C₂₀ alkenyl group, and at least one of R₁₁₋₂ to R₁₃₋₂ is a C₂ to C₂₀ alkenyl group, R₁₄₋₂ to R₁₇₋₂ are each independently selected from the group consisting of hydrogen, a C₁ to C₂₀ alkyl group, and a C₂ to C₂₀ alkenyl group, and at least one of R₁₄₋₂ to R₁₇₋₂ is a C₂ to C₂₀ alkenyl group, R₁₈₋₂ to R₂₀₋₂ are each independently selected from the group consisting of hydrogen, a C₁ to C₂₀ alkyl group, and a C₂ to C₂₀ alkenyl group, and n₁₋₂₁ and n₁₋₂₂ are 100 to 500;

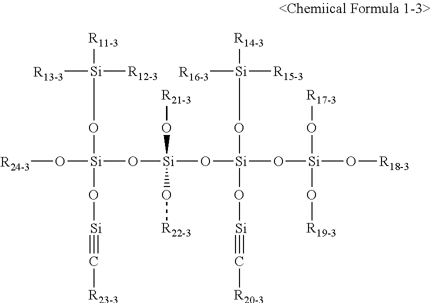

wherein, in Chemical Formula 1-3, R₁₁₋₃ to R₁₃₋₃ are each independently selected from the group consisting of hydrogen, a C₁ to C₂₀ alkyl group, and a C₂ to C₂₀ alkenyl group, and at least one of R₁₁₋₃ to R₁₃₋₃ is a C₂ to C₂₀ alkenyl group, and R₁₄₋₃ to R₂₄₋₃ are each independently selected from the group consisting of hydrogen, a C₁ to C₂₀ alkyl group, and a C₂ to C₂₀ alkenyl group.

The base resin may include: 70.0 to 90.0 wt % of the siloxane-based compound represented by Chemical Formula 1-1; 1.0 to 20.0 wt % of the siloxane-based compound represented by Chemical Formula 1-2; and 5.0 to 25.0 wt % of the siloxane-based compound represented by Chemical Formula 1-3.

The base resin may include a siloxane-based compound represented by Chemical Formula 2 below:

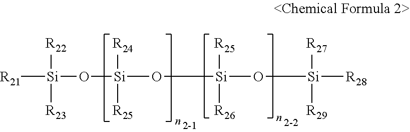

wherein, in Chemical Formula 2, R₂₁ to R₂₉ are each independently selected from the group consisting of hydrogen and a C₁ to C₂₀ alkyl group, and n₂₋₁ and n₂₋₂ are each independently 1 to 100.

The siloxane-based compound represented by Chemical Formula 2 may be a siloxane-based compound represented by Chemical Formula 2-1 below:

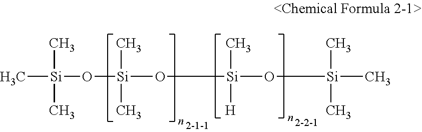

wherein, in Chemical Formula 2-1, n₂₋₁₋₁ and n₂₋₂₋₁ are each independently 1 to 100.

The base resin may include 1.0 to 26.0 wt % of the siloxane-based compound represented by Chemical Formula 2.

The (meth)acrylic diffusion agent may include one or more selected from the group consisting of polyalkyl (meth)acrylate; polyalkyl (meth)acrylate-co-polystyrene; a mixture of polyalkyl (meth)acrylate and polycarbonate; a mixture of polyalkyl (meth)acrylate and silica; and a mixture of polyalkyl (meth)acrylate and polyoxymethylene.

The polyalkyl (meth)acrylate may be polymethylmethacrylate.

The (meth)acrylic diffusion agent may have an average particle size of 0.5 to 5.0 μm.

The (meth)acrylic diffusion agent may have a refractive index of 1.450 to 1.540.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view illustrating a module according to one embodiment of the present invention.

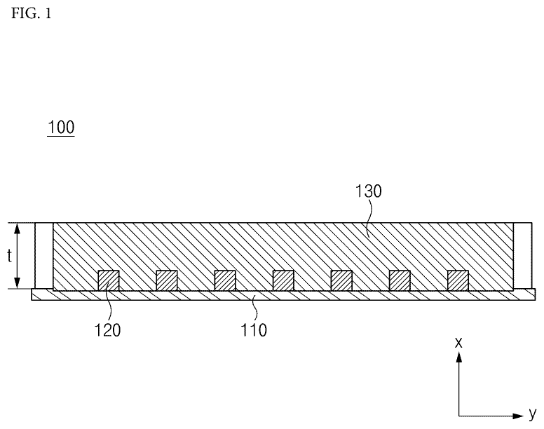

### DETAILED DESCRIPTION

Hereinafter, embodiments will be described in further detail to help understand the present invention.

Terms and words used in the specification and claims should not be construed as limited to general or dictionary meanings, and based on the principle that the inventors have appropriately defined the concepts of terms in order to explain the invention in the best way, the terms and words should be interpreted with the meaning and concept which are consistent with the technical spirit of the present invention.

The present invention is directed to a module that can achieve a uniform, high-luminance surface light source without applying a separate optical system and form a diffusion layer that can be directly molded onto the surface light source.

In the present invention, an alkyl group refers to a linear or cyclic alkyl group, and the number of carbons is not particularly limited. However, the alkyl group may be a C₁ to C₂₀ alkyl group, preferably, a C₁ to C₁₅ alkyl group, more preferably, a C₁ to C₁₀ alkyl group, and most preferably, a C₁ to C₅ alkyl group. The alkyl group may be additionally substituted with another substituent. A specific example of the alkyl group may be a methyl group, an ethyl group, a n-propyl group, an isopropyl group, a n-butyl group, an isobutyl group, a tert-butyl group, a sec-butyl group, a 1-methyl-butyl group, a 1-ethyl-butyl group, an n-pentyl group, an isopentyl group, a neopentyl group, a tert-pentyl group, an n-hexyl group, a 1-methylpentyl group, a 2-methylpenthyl group, a 4-methyl-2-pently group, a 3,3-dimethylbutyl group, a 2-ethylbutyl group, an n-heptyl group, a 1-methylhexyl group, a cyclopentylmethyl group, a cyclopentylmethyl group, a cyclohexylmethyl group, an n-octyl group, a tert-octyl group, a 1-methylheptyl group, a 2-ethylhexyl group, a 2-propylpentyl group, an n-nonyl group, a 2,2-dimethylheptyl group, a 1-ethyl-propyl group, a 1,1-dimethyl-propyl group, an isohexyl group, a 2-methylpentyl group, a 4-methylhexyl group, or a 5-methylhexyl group, but the present invention is not limited thereto.

In the present invention, an alkenyl group may be a linear or cyclic alkenyl group, and the number of carbons is not particularly limited. However, the alkenyl group may be a C₂ to C₂₀ alkenyl group, preferably, a C₂ to C₁₅ alkenyl group, more preferably, a C₂ to C₁₀ alkenyl group, and most preferably, a C₂ to C₅ alkenyl group. The alkenyl group may be further substituted with another substituent. The alkenyl group may be vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butandienyl, allyl, 1-phenylvinyl-1-yl, 2-phenylvinyl-1-yl, 2,2-diphenylvinyl-1-yl, 2-phenyl-2-(naphthyl-1-yl) vinyl-1-yl, 2,2-bis(diphenyl-1-yl) vinyl-1-yl, stylbenyl, or styrenyl, but the present invention is not limited thereto.

In the present invention, an alkyl (meth)acrylate may encompass alkyl acrylate and alkyl methacrylate. The alkyl (meth)acrylate may be a C₁ to C₁₀ alkyl (meth)acrylate, and may be one or more selected from methyl (meth)acrylate, ethyl (meth)acrylate, propyl (meth)acrylate, butyl (meth)acrylate, heptyl(meth)acrylate, hexyl(meth)acrylate, 2-ethylhexyl (meth)acrylate, and decyl(meth)acrylate, and preferably, methylmethacrylate.

In the present invention, the particle size and particle size distribution may be measured by a laser scattering particle size analyzer (Manufacturer: HORIBA, Model name: LA-950, Supplier: Trendtop Scientific Corp., Taipei, Taiwan). The average particle size may mean the average value of the particle sizes of 10 measurement targets.

In the present invention, the refractive index may be measured using a spectrophotometer (Manufacturer: Shimadzu, Model name: UV-2600). The refractive index (n) may be calculated based on Brewster's law (n=\sqrt{1/T}) by measuring the transmittance (T) of light at a specific wavelength.

In the present invention, the transmittance of the module may be derived by the following equation.

$$I / {I}_{0} = exp \{ ( - 3 {Lxr}^{3} ) ( {n}_{d} / {n}_{s} - 1 ) 4 {λ}^{4} \}$$

I: Output intensity

I₀: Input intensity
x: Thickness of module
L: Concentration of diffusion agent
r: Particle radius of diffusion agent
n_{d}: Refractive index of diffusion agent
nₛ: Refractive index of base resin
λ: Wavelength of light-emitting device

In the present invention, the output intensity (I) may be measured using a vehicle light source (Manufacturer: Impress Sensor & Systems, Model name: LMK 598). The unit of the output intensity (I) is candela (cd). The output intensity (I) may be measured by detecting the sensitivity of the light output from the module using an optical sensor.

In the present invention, the input intensity (I₀) may be measured using a power meter (Manufacturer: Thorlabs, Model name: PM100D). The unit of the input intensity (I₀) is candela (cd). The input intensity (I₀) may be measured as the amount of light coming from a light emitting device (LED) into an optical sensor.

In the present invention, the thickness (x) of the module may be measured using a micrometer, or a digital thickness gauge.

In the present invention, the concentration (L) of the diffusion agent may be measured using a laser scattering particle size analyzer. The concentration of the diffusion agent is calculated by the following equation based on the degree of scattering based on the Mie theory and is automatically calculated by a laser scattering particle size analyzer.

$$C = α \cdot L - ln ( T )$$

C: Particle concentration
α: Absorption coefficient (inherent particle property)
L: Length of path of light passing through sample
T: Transmittance

In the present invention, the particle radius (r) of the diffusion agent may be measured using a laser scattering particle size analyzer, and the average particle size may refer to the average value of 10 measurement targets.

In the present invention, a wavelength (λ) may be measured using a spectrum analyzer (Manufacturer: Horiba, Model name: LabSpec). The wavelength band of the light-emitting device entering the optical sensor may be measured.

In the present invention, a beam angle indicates the range in which the light source emits light, and may be measured using a goniophotometer (Manufacturer: Withlight, Model name: OPI-305). The intensity distribution curve data of the beam may be obtained, and the beam angle may be calculated as the angle between the two points at the center of the beam where the intensity decreases to 50% of the maximum value.

### 1. Module

A module according to one embodiment of the present invention comprises a circuit board; a light-emitting device placed on the circuit board; and a diffusion layer placed on the light-emitting device, wherein the diffusion layer is formed of a composition for forming a diffusion layer, wherein the composition comprises a base resin comprising a siloxane-based compound; and a (meth)acrylic diffusion agent, and the content of the (meth)acrylic diffusion agent based on a total weight of the composition is 1.0 to 10.0 wt %.

The figure is a view illustrating a module according to one embodiment of the present invention.

Referring to the figure, a module 100 includes a circuit board 110, a light-emitting device 120, and a diffusion layer 130. The thickness of the diffusion layer 130 is expressed as t.

Hereinafter, the module according to one embodiment of the present invention will be described in detail.

### 1) Circuit Board

The circuit board may include a printed circuit board (PCB). The PCB may comprise one or more selected from a metal-core PCB, a flexible PCB, a ceramic PCB, and a rigid PCB.

A wiring layer may be comprised on the circuit board, and the wiring layer may be electrically connected to the light-emitting device.

A connector may be comprised on the circuit board and supply power to the light-emitting device. The connector may be disposed on a part of the top or bottom surface of the circuit board.

### 2) Light-Emitting Device

A plurality of light-emitting devices may be placed on the circuit board. The light-emitting devices may be electrically connected in series, parallel, or series-parallel by the wiring layer.

The light-emitting device is a light-emitting diode chip, and may emit at least one of blue light, red light, green light, UV light, and IR light. The light-emitting device may emit at least one of blue light, red light, and green light.

The light-emitting device may have a beam angle of 120° or more when emitting light from the top surface.

The light-emitting device may have a beam angle of 140° or more when emitting light from the side surface.

The light-emitting device may be a 5-sided light-emitting device.

### 3) Diffusion Layer

The diffusion layer is formed of a composition for forming a diffusion layer. The composition comprises a base resin comprising a siloxane-based compound; and a (meth)acrylic diffusion agent, and the content of the (meth)acrylic diffusion agent based on a total weight of the composition is 1.0 to 10.0 wt %.

The diffusion layer may be formed by thermally curing the composition for forming a diffusion layer, and specifically, by thermally curing the composition for forming a diffusion layer twice or more.

The composition for forming a diffusion layer may be subjected to primary thermal curing at 35 to 65° C., preferably, 40 to 60° C., and more preferably, 45 to 55° C. When the conditions described above are satisfied, the diffusion agent may be uniformly distributed within the base resin, and the basic curing reaction may proceed. In addition, since the viscosity does not change rapidly during thermal curing, bubbles do not form and surface roughness can be appropriately maintained.

The composition for forming a diffusion layer that has experienced primary thermal curing may be subjected to secondary thermal curing at 120 to 180° C., preferably, 130 to 170° C., and more preferably, 140 to 160° C. When the conditions described above are satisfied, thermal decomposition and yellowing may not occur, and as a result, optical performance and durability may be improved.

The light-emitting device may be in-molded within the diffusion layer. Through the above diffusion layer, a uniform and high-luminance surface light source may be achieved without applying a separate optical system.

The thickness of the diffusion layer may be 3 to 30 nm, preferably, 3.5 to 25 nm, and more preferably, 4.0 to 10.0 nm. When the conditions described above are satisfied, the light path is properly maintained, so diffusion is sufficiently implemented, and the hotspot phenomenon where the light source is locally concentrated may be minimized. In addition, since light may escape well from the diffusion layer, the creation of dark spots due to reduced luminance may be minimized.

The composition for forming a diffusion layer includes a base resin comprising a siloxane-based compound; and a (meth)acrylic diffusion agent, and the content of the (meth)acrylic diffusion agent is 3.0 to 7.0 wt %.

### (1) Base Resin

The base resin comprises a siloxane-based compound.

An epoxy resin or UV resin, which is conventionally used as a base resin, has a considerable amount of heat discoloration due to its own characteristics. However, since the base resin comprises a siloxane-based compound, heat discoloration occurs significantly less than with conventional base resins. As a result, the module manufactured with the composition for preparing a diffusion agent is highly reliable and has relatively excellent color stability.

The siloxane-based compound may comprise a substituent represented by Chemical Formula 1 below:

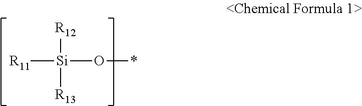

In Chemical Formula 1, R₁₁ to R₁₃ are each independently hydrogen, a C₁ to C₂₀ alkyl group, or a C₂ to C₂₀ alkenyl group, wherein at least one of R₁₁ to R₁₃ is a C₂ to C₂₀ alkenyl group.

In Chemical Formula 1, R₁₁ to R₁₃ may each be independently preferably hydrogen, a C₁ to C₁₅ alkyl group, or a C₂ to C₁₅ alkenyl group, wherein at least one of R₁₁ to R₁₃ may be a C₂ to C₁₅ alkenyl group; more preferably, hydrogen, a C₁ to C₁₀ alkyl group, or a C₂ to C₁₀ alkenyl group, wherein at least one of R₁₁ to R₁₃ may be a C₂ to C₁₀ alkenyl group; and most preferably, hydrogen, a C₁ to C₅ alkyl group, or a C₂ to C₅ alkenyl group, wherein at least one of R₁ to R₁₃ may be a C₂ to C₅ alkenyl group.

Since the siloxane-based compound including a substituent represented by Chemical Formula 1 comprises an alkenyl group, it can participate in a crosslinking reaction. Therefore, by forming or reinforcing a polymer network within the base resin, durability and stability may be increased not only in the natural environment but also in harsh environments such as high temperature and chemical environments.

The base resin may comprise one or more selected from a siloxane-based compound represented by Chemical Formula 1-1 below, a siloxane-based compound represented by Chemical Formula 1-2 below, and a siloxane-based compound represented by Chemical Formula 1-3 below:

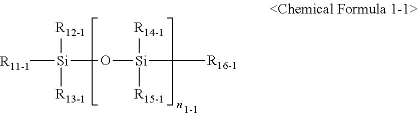

In Chemical Formula 1-1, R₁₁₋₁ to R₁₃₋₁ are each independently hydrogen, a C₁ to C₂₀ alkyl group, or a C₂ to C₂₀ alkenyl group, wherein at least one of R₁₁₋₁ to R₁₃₋₁ is a C₂ to C₂₀ alkenyl group, R₁₄₋₁ and R₁₅₋₁ are each independently hydrogen or a C₁ to C₂₀ alkyl group, R₁₆₋₁ is hydrogen, a C₁ to C₂₀ alkyl group, or a C₂ to C₂₀ alkenyl group, and n₁₋₁ is 100 to 500;

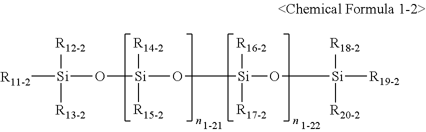

In Chemical Formula 1-2, R₁₁₋₂ to R₁₃₋₂ are each independently hydrogen, a C₁ to C₂₀ alkyl group, or a C₂ to C₂₀ alkenyl group, wherein at least one of R₁₁₋₂ to R₁₃₋₂ is a C₂ to C₂₀ alkenyl group, R₁₄₋₂ to R₁₇₋₂ are each independently hydrogen, a C₁ to C₂₀ alkyl group, or a C₂ to C₂₀ alkenyl group, wherein at least one of R₁₄₋₂ to R₁₇₋₂ is a C₂ to C₂₀ alkenyl group, R₁₈₋₂ to R₂₀₋₂ are each independently hydrogen, a C₁ to C₂₀ alkyl group, or a C₂ to C₂₀ alkenyl group, and n₁₋₂₁ and n₁₋₂₂ are 100 to 500;

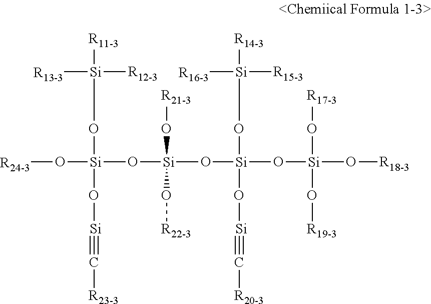

In Chemical Formula 1-3, R₁₁₋₃ to R₁₃₋₃ are each independently hydrogen, a C₁ to C₂₀ alkyl group, or a C₂ to C₂₀ alkenyl group, wherein at least one of R₁₁₋₃ to R₁₃₋₃ is a C₂ to C₂₀ alkenyl group, and R₁₄₋₃ to R₂₄₋₃ are each independently hydrogen, a C₁ to C₂₀ alkyl group, or a C₂ to C₂₀ alkenyl group.

In Chemical Formula 1-1, R₁₁₋₁ to R₁₃₋₁ are each independently hydrogen, a C₁ to C₁₅ alkyl group, or a C₂ to C₁₅ alkenyl group, wherein at least one of R₁₁₋₁ to R₁₃₋₁ may be a C₂ to C₁₅ alkenyl group; preferably, hydrogen, a C₁ to C₁₀ alkyl group, or a C₂ to C₁₀ alkenyl group, wherein at least one of R₁₁₋₁ to R₁₃₋₁ is a C₂ to C₁₀ alkenyl group; more preferably, hydrogen, a C₁ to C₅ alkyl group, or a C₂ to C₅ alkenyl group, wherein at least one of R₁₁₋₁ to R₁₃₋₁ is a C₂ to C₅ alkenyl group.

In Chemical Formula 1-1, R₁₄₋₁ and R₁₅₋₁ are each independently preferably hydrogen or a C₁ to C₁₅ alkyl group; more preferably, hydrogen or a C₁ to C₁₀ alkyl group; and most preferably, hydrogen or a C₁ to C₅ alkyl group.

In Chemical Formula 1-1, R₁₆₋₁ is preferably hydrogen, a C₁ to C₁₅ alkyl group, or a C₂ to C₁₅ alkenyl group; more preferably, hydrogen, a C₁ to C₁₀ alkyl group or a C₂ to C₁₀ alkenyl group; and most preferably, hydrogen, a C₁ to C₅ alkyl group, or a C₂ to C₅ alkenyl group.

In Chemical Formula 1-1, n₁₋₁ is preferably 100 to 400, more preferably, 150 to 500, and most preferably, 300 to 500. When the conditions described above are satisfied, light may be evenly diffused, and excellent light transmittance may be realized.

In Chemical Formula 1-2, R₁₁₋₂ to R₁₃₋₂ are each independently preferably hydrogen, a C₁ to C₁₅ alkyl group, or a C₂ to C₁₅ alkenyl group, wherein at least one of R₁₁₋₂ to R₁₃₋₂ is a C₂ to C₁₅ alkenyl group; more preferably, hydrogen, a C₁ to C₁₀ alkyl group, or a C₂ to C₁₀ alkenyl group, wherein at least one of R₁₁₋₂ to R₁₃₋₂ is a C₂ to C₁₀ alkenyl group; and most preferably, hydrogen, a C₁ to C₅ alkyl group, or a C₂ to C₅ alkenyl group, wherein at least one of R₁₁₋₂ to R₁₃₋₂ is a C₂ to C₅ alkenyl group.

In Chemical Formula 1-2, R₁₄₋₂ to R₁₇₋₂ are each independently preferably hydrogen, a C₁ to C₁₅ alkyl group, or a C₂ to C₁₅ alkenyl group, wherein at least one of R₁₄₋₂ to R₁₇₋₂ is a C₂ to C₁₅ alkenyl group; more preferably, hydrogen, a C₁ to C₁₀ alkyl group, or a C₂ to C₁₀ alkenyl group, wherein at least one of R₁₄₋₂ to R₁₇₋₂ is a C₂ to C₁₀ alkenyl group; and most preferably, hydrogen, a C₁ to C₅ alkyl group, or a C₂ to C₅ alkenyl group, wherein at least one of R₁₄₋₂ to R₁₇₋₂ is a C₂ to C₅ alkenyl group.

In Chemical Formula 1-2, R₁₈₋₂ to R₂₀₋₂ are each independently preferably hydrogen, a C₁ to C₁₅ alkyl group, or a C₂ to C₁₅ alkenyl group; more preferably, hydrogen, a C₁ to C₁₀ alkyl group, or a C₂ to C₂₅ alkenyl group; and most preferably, hydrogen, a C₁ to C₅ alkyl group, or a C₂ to C₅ alkenyl group.

In Chemical Formula 1-2, n₁₋₂₁ and n₁₋₂₂ are preferably 100 to 400, more preferably, 150 to 500, and most preferably, 300 to 500. When the conditions described above are satisfied, light may be evenly diffused, and excellent light transmittance may be realized.

In Chemical Formula 1-3, R₁₁₋₃ to R₁₃₋₃ are each independently preferably hydrogen, a C₁ to C₁₅ alkyl group, or a C₂ to C₁₅ alkenyl group, wherein at least one of R₁₁₋₃ to R₁₃₋₃ is a C₂ to C₁₅ alkenyl group; more preferably, hydrogen, a C₁ to C₁₀ alkyl group, or a C₂ to C₁₀ alkenyl group, wherein at least one of R₁₁₋₃ to R₁₃₋₃ is a C₂ to C₁₀ alkenyl group; and most preferably, hydrogen, a C₁ to C₅ alkyl group, or a C₂ to C₅ alkenyl group, wherein at least one of R₁₁₋₃ to R₁₃₋₃ is a C₂ to C₅ alkenyl group.

In Chemical Formula 1-3, R₁₄₋₃ to R₂₄₋₃ are each independently preferably hydrogen, a C₁ to C₁₅ alkyl group, or a C₂ to C₁₅ alkenyl group; more preferably, hydrogen, a C₁ to C₁₀ alkyl group, or a C₂ to C₁₀ alkenyl group; and most preferably, hydrogen, a C₁ to C₅ alkyl group, or a C₂ to C₅ alkenyl group.

The siloxane-based compound represented by Chemical Formula 1-1 may be a siloxane-based compound represented by Chemical Formula 1-1-1 below:

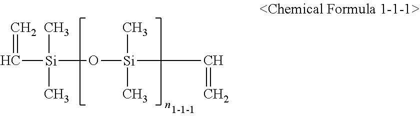

In Chemical Formula 1-1-1,
n₁₋₁₋₁ is 100 to 500.

In Chemical Formula 1-1-1, n₁₋₁₋₁ is preferably 100 to 400, more preferably, 150 to 300, and most preferably, 300 to 500. When the conditions described above are satisfied, light may be evenly diffused, and excellent light transmittance may be realized.

The siloxane-based compound represented by Chemical Formula 1-2 may be a siloxane-based compound represented by Chemical Formula 1-2-1 below:

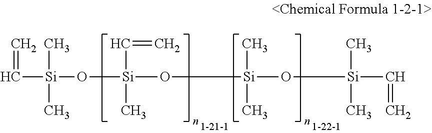

In Chemical Formula 1-2-1, n₁₋₂₁₋₁ and n₁₋₂₂₋₁ are each independently 100 to 500.

In Chemical Formula 1-2-1, n₁₋₂₁₋₁ and n₁₋₂₂₋₁ are each independently preferably 100 to 400, more preferably, 150 to 300, and most preferably, 300 to 500. When the conditions described above are satisfied, light may be evenly diffused, and excellent light transmittance may be realized.

The siloxane-based compound represented by Chemical Formula 1-3 may be a siloxane-based compound represented by Chemical Formula 1-3-1 below:

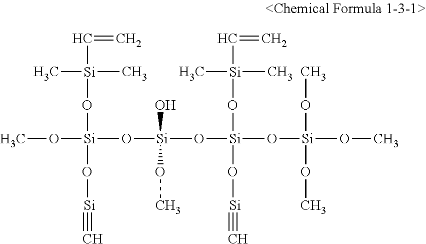

Meanwhile, the base resin may be a mixture including two or more siloxane-based compounds comprising a substituent represented by Chemical Formula 1. Specifically, the base resin may be a mixture comprising two or more selected from the siloxane-based compound represented by Chemical Formula 1-1, the siloxane-based compound represented by Chemical Formula 1-2, and the siloxane-based compound represented by Chemical Formula 1-3.

The base resin comprising the above mixture may maximize the performance of the module including a light-emitting device, and specifically, an automobile module including a light-emitting device, in various aspects, such as heat resistance, chemical resistance, water resistance, improved optical properties, improved mechanical strength, improved thermal conductivity, and environmental friendliness. As a result, the module is able to ensure a long life, excellent performance and stability, and can operate reliably even in harsh environments. Particularly, when the base resin comprises the siloxane-based compound represented by Chemical Formula 1-3, the diffusion or optical uniformity of light can be improved, and light can be efficiently transmitted.

In addition, the base resin may comprise the siloxane-based compound represented by Chemical Formula 1-1 at 70.0 to 90.0 wt %, preferably, 73.0 to 86.0 wt %, and more preferably, 76.0 to 83.0 wt % with respect to the total weight of the base resin. When the conditions described above are satisfied, the physical stability and durability of the diffusion layer formed of the composition for forming a diffusion layer may be improved, and the deterioration of processibility and permeability may be minimized. Accordingly, even being used for a long time, the module including the diffusion layer can have less performance degradation and increased resistance against environmental changes. As a result, the module including the diffusion layer may be applied to an automobile signal lamp requiring high reliability.

The base resin may comprise the siloxane-based compound represented by Chemical Formula 1-2 at 1.0 to 20.0 wt %, preferably, 2.0 to 15.0 wt %, and more preferably, 4.0 to 11.0 wt % with respect to the total weight of the base resin. When the conditions described above are satisfied, chemical stability may be reinforced, and the chemical resistance and environmental resistance of the diffusion layer formed of the composition for forming a diffusion layer may be improved. In addition, the mechanical strength of the diffusion layer may be adequately maintained, and the flexibility and permeability of the diffusion layer may be minimized.

The base resin may comprise the siloxane-based compound represented by Chemical Formula 1-3 at 5.0 to 25.0 wt %, preferably, 7.0 to 21.0 wt %, and more preferably, 10.0 to 17.0 wt % with respect to the total weight of the base resin. When the conditions described above are satisfied, the transparency, surface hardness, chemical resistance, and durability of the diffusion layer formed of the composition for forming a diffusion layer may be improved. In addition, the surface of the diffusion layer may be formed more uniformly. In addition, the degradation of the processibility and permeability of the diffusion layer may be minimized.

Meanwhile, the base resin may further comprise a siloxane-based compound represented by Chemical Formula 2 below:

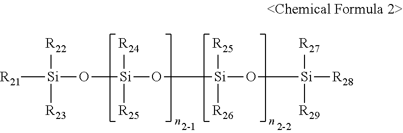

In Chemical Formula 2, R₂₁ to R₂₉ are each independently hydrogen or a C₁ to C₂₀ alkyl group, and n₂₋₁ and n₂₋₂ are each independently 1 to 100.

In Chemical Formula 2, R₂₁ to R₂₉ are each independently preferably hydrogen or a C₁ to C₁₅ alkyl group; more preferably, hydrogen or a C₁ to C₁₀ alkyl group; and most preferably, hydrogen or a C₁ to C₅ alkyl group.

In Chemical Formula 2, n₂₋₁ and n₂₋₂ are each independently preferably 1 to 80, more preferably, 1 to 60, and most preferably, 1 to 40. When the conditions described above are satisfied, reactivity is not high, so the compound may be chemically stable.

The siloxane-based compound represented by Chemical Formula 2 may be a siloxane-based compound represented by Chemical Formula 2-1 below:

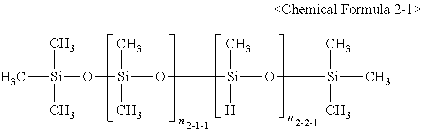

In Chemical Formula 2-1, n₂₋₁₋₁ and n₂₋₂₋₁ are each independently 1 to 100.

In Chemical Formula 2, n₂₋₁₋₁ and n₂₋₂₋₁ are each independently preferably 1 to 80, more preferably, 1 to 60, and most preferably, 1 to 40. When the conditions described above are satisfied, reactivity is not high, so the compound may be chemically stable.

The base resin may comprise the siloxane-based compound represented by Chemical Formula 2 at 1.0 to 26.0 wt %; preferably, 1.5 to 23.0 wt %; and more preferably, 2.0 to 20.0 wt % with respect to the total weight of the base resin. When the conditions described above are satisfied, the diffusion layer formed of the composition for forming a diffusion layer may maintain safety even at high temperatures, and its chemical resistance and durability may be further improved. In addition, the diffusion layer may have excellent flexibility, thereby improving impact absorption capacity.

The base resin may comprise the siloxane-based compound having a substituent represented by Chemical Formula 1, at 74.0 to 99.0 wt %; preferably, 77.0 to 98.5 wt %; and more preferably, 80.0 to 98.0 wt % with respect to the total weight of the base resin. When the conditions described above are satisfied, the diffusion layer formed of the composition for forming a diffusion layer may maintain safety even at high temperatures, and its chemical resistance and durability may be further improved. In addition, the diffusion layer may have excellent flexibility, thereby improving impact absorption capacity.

When the base resin comprises the siloxane-based compound represented by Chemical Formula 2, the base resin may comprise one or more selected from the siloxane-based compound represented by Chemical Formula 1-1, the siloxane-based compound represented by Chemical Formula 1-2, and the compound represented by Chemical Formula 1-3.

Meanwhile, the viscosity of the base resin may be 4,000 to 10,000 cP, preferably, 4,000 to 8,000 cP, and more preferably, 4,000 to 6,000 cP. When the conditions described above are satisfied, it has the advantage of ensuring fluidity with an appropriate amount of viscosity, making it easy to manufacture and process, and preventing the sedimentation of particles, thereby maintaining a uniform distribution of particles.

Here, the viscosity of the base resin may be measured according to ASTM D445 or ASTM D2196 at 25° C. The viscosity may be measured using a rotational viscometer, and can be analyzed by measuring the resistance generated when a sample is rotated after being placed in a specific standard jig or carrier.

The base resin may use a commercially available material, and specifically, one or more selected from SL3512A and SL3512B of KCC Corp. may be used.

### (2) (Meth)acrylic Diffusion Agent

The (meth)acrylic diffusion agent not only has excellent compatibility with the above-described base resin, but also improves diffusion properties, thereby enabling the composition for forming a diffusion layer to form a diffusion layer that can achieve a high-luminance surface light source.

The (meth)acrylic diffusion agent may comprise one or more selected from polyalkyl (meth)acrylate; polyalkyl (meth)acrylate-co-polystyrene; a mixture of polyalkyl (meth)acrylate and polycarbonate; a mixture of polyalkyl (meth)acrylate and silica; and a mixture of polyalkyl (meth)acrylate and polyoxymethylene.

Here, the polyalkyl (meth)acrylate may have a crosslinked or uncrosslinked structure, and the polyalkyl (meth)acrylate may be polymethylmethacrylate.

The (meth)acrylic diffusion agent may have an average particle size of 0.5 to 5.0 μm, preferably, 1.0 to 4.5 μm, and more preferably, 1.5 to 4.0 μm. Even though luminosity decreases as the average particle size increases, when the conditions described above are satisfied, the module manufactured of the composition for forming a diffusion layer may achieve excellent transmittance.

It is preferable that the (meth)acrylic diffusion agent is a spherical particle with excellent permeability due to the presence of uniform gaps due to the arrangement of particles.

The (meth)acrylic diffusion agent may have a refractive index of 1.450 to 1.540, preferably, 1.465 to 1.525, and more preferably, 1.480 to 1.510. The higher the refractive index, the more the light bends, so the phenomenon of light being trapped occurs. However, when the conditions described above are satisfied, excellent optical efficiency may be achieved.

The composition for forming a diffusion layer may comprise the (meth)acrylic diffusion agent at 1.0 to 10.0 wt %, preferably, 3.0 to 8.0 wt %, and more preferably, 4.0 to 6.0 wt %. When the (meth)acrylic diffusion agent is included in a smaller amount than the conditions described above, a hot spot phenomenon in which the light source is locally concentrated may occur due to an insufficient diffusion effect, and when included in a larger amount than the conditions described above, problems such as reduced optical performance and reduced luminance may occur due to excessive scattering.

The composition for forming a diffusion layer may comprise the base resin as the remainder such that the total weight of the composition for forming a diffusion layer becomes 100 wt %.

Hereinafter, to help in understanding the present invention, exemplary examples will be suggested. However, it should be understood that the examples are not provided to limit the scope of the present invention and all alternatives and modifications within the scope of the accompanying claims are included in the present invention.

### EXAMPLES AND COMPARATIVE EXAMPLES

The description of the components used in the following examples and comparative examples is as follows.

### 1) Base Resin

(1) Mixture of siloxane-based compounds: mixture of SL3512A (Product name, Manufacturer: KCC Corp., mixture of the siloxane-based compound represented by Chemical Formula 1-1-1, the siloxane-based compound represented by Chemical Formula 1-2-1, and the siloxane-based compound represented by Chemical Formula 1-3-1), and SL3512B (Product name, Manufacturer: KCC Corp., mixture of the siloxane-based compound represented by Chemical Formula 1-1-1 and the siloxane-based compound represented by Chemical Formula 2-1) in a weight ratio of 3:1

### 2) Diffusion Agent

(1) Crosslinked polymethylmethacrylate (crosslinked PMMA, Average particle size: 2 μm, Refractive index: 1.495, Specific gravity: 1.2 g/mm³, Shape: spherical, and Heat deflection temperature: 280° C.)

### <Preparation of Composition for Forming Diffusion Layer>

Compositions for forming a diffusion layer was prepared with a base resin and a diffusion agent at contents described in Tables 1 to 3 below.

### <Manufacture of Module>

A circuit board with light-emitting devices arranged in the molding space of a lower mold into which the composition for forming a diffusion layer of each example or comparative example was injected was placed, and then thermal curing was performed. Specifically, the circuit board was placed so that the light-emitting devices were immersed in the molding space of the lower mold into which the composition for forming a diffusion layer of each example or comparative example was injected, and then put into a vacuum oven. Next, the composition was primarily cured at 50° C. for 60 minutes and then secondarily cured at 150° C. for 90 minutes, thereby manufacturing a module.

### Experimental Example 1

The modules of the examples and the comparative examples were used to evaluate physical properties by the methods described below, and the results are shown in Tables 1 to 3 below.

1) Average luminance (units: nit): It was measured using a spectroradiometer (Manufacturer: Konica Minolta, Model name: CS-2000). Specifically, after setting a sample light source perpendicular to the surface of the light source at a reference measurement distance of 1 m, the luminance was measured individually by selecting 9 grid points at regular intervals, and the arithmetic mean of the luminance values of all measured points was calculated.

2) Standard deviation of luminance (units: nit): It is an index that evaluates the uniformity of the luminance of a light source, indicating how much the luminance of each measurement point deviates from the average luminance. A luminance deviation was obtained by calculating the standard deviation using the average and each luminance measurement value.

3) Central luminosity (units: cd): It refers to the light intensity (units: cd) at the center (horizontal: 0°, vertical: 0°) 0°. A central luminosity is used to evaluate the light distribution characteristics of an automotive lighting system and is measured using a goniometer for vehicles (Manufacturer: Impress Sensor & Systems, Model name: LMK 598). The intensity of light emitted from the module was detected and then measured using an optical sensor of the goniometer for vehicles.

TABLE 1

| Classification | | Example 1 | Example 2 | Example 3 | Example 4 | Example 5 |
|---|---|---|---|---|---|---|
| Composition | Mixture of | 99 | 98 | 97 | 96 | 95 |
| for forming | siloxane- | | | | | |
| diffusion | based | | | | | |
| layer | compounds | | | | | |
| (wt %) | Crosslinked | 1 | 2 | 3 | 4 | 5 |
| | PMMA | | | | | |

| | | | | | |
|---|---|---|---|---|---|
| Average luminance (nit, | 20,739 | 20,294 | 18,378 | 15,539 | 12,299 |
| cd/m²) | | | | | |
| Standard deviation of | 8,850 | 5,112 | 3,912 | 2,579 | 2,358 |
| luminance (nit) | | | | | |
| Central luminosity (cd) | 518.4 | 507.3 | 459.4 | 388.4 | 307.4 |

TABLE 2

| Classification | | Example 6 | Example 7 | Example 8 | Example 9 | Example 10 |
|---|---|---|---|---|---|---|
| Composition | Mixture of | 94 | 93 | 92 | 91 | 90 |
| for forming | siloxane- | | | | | |
| diffusion | based | | | | | |
| layer | compounds | | | | | |
| (wt %) | Crosslinked | 6 | 7 | 8 | 9 | 10 |
| | PMMA | | | | | |

| | | | | | |
|---|---|---|---|---|---|
| Average luminance (nit, | 9,532 | 8,000 | 5,800 | 5.625 | 4,560 |
| cd/m²) | | | | | |
| Standard deviation of | 2,151 | 2,197 | 2,264 | 2,271 | 2,289 |
| luminance (nit) | | | | | |
| Central luminosity (cd) | 238.3 | 215.2 | 145.1 | 115.2 | 89.5 |

TABLE 3

| | | Comparative | Comparative | Comparative | Comparative | Comparative |
|---|---|---|---|---|---|---|
| Classification | | Example 1 | Example 2 | Example 3 | Example 4 | Example 5 |
| Composition | Mixture of | 89.0 | 88.0 | 87.0 | 86.0 | 85.0 |
| for forming | siloxane- | | | | | |
| diffusion | based | | | | | |
| layer | compounds | | | | | |
| (wt %) | Crosslinked | 11.0 | 12.0 | 13.0 | 14.0 | 15.0 |
| | PMMA | | | | | |

| | | | | | |
|---|---|---|---|---|---|
| Average luminance (nit, | 4.520 | 4.320 | 4.215 | 4.115 | 4.089 |
| cd/m²) | | | | | |
| Standard deviation of | 3,190 | 3,950 | 4,025 | 4,052 | 4,061 |
| luminance (nit) | | | | | |
| Central luminosity (cd) | 69.5 | 60.2 | 40.4 | 35.2 | 30.1 |

Referring to Tables 1 to 3, it can be seen that, in Examples 1 to 10 where the content of crosslinked PMMA is 1.0 to 10.0 wt %, compared to Comparative Examples 1 to 5 where the content of crosslinked PMMA is more than 10.0 wt %, the central luminosity decreases below 80 cd.

In addition, as the content of crosslinked PMMA increased, the standard deviation decreased and the uniformity of luminance was excellent, but the standard deviation increased when comparing Example 10 with Comparative Example 1. That is, it can be seen that even when the concentration of crosslinked PMMA increases, the standard deviation of the luminance does not improve, and once it reaches a certain level, no significant change occurs. In addition, Comparative Examples 1 to 5 showed an excessively low central luminosity.

In a module according to the present invention, a diffusion layer can be directly molded onto a surface light source to achieve a uniform, high-luminance surface light source without applying a separate optical system.

What is claimed is:

1. A module comprising:
a circuit board; a light-emitting device placed on the circuit board; and a diffusion layer placed on the light-emitting device,
wherein the diffusion layer is formed of a composition for forming a diffusion layer,
wherein the composition comprises a base resin comprising a siloxane-based compound; and a (meth)acrylic diffusion agent, and
wherein a content of the (meth)acrylic diffusion agent based on a total weight of the composition is 1.0 to 10.0 wt %.

2. The module of claim 1, wherein the diffusion layer is a single layer covering the light-emitting device.

3. The module of claim 1, wherein the light-emitting device has a beam angle of 120° or more when emitting light from a top surface of the light-emitting device.

4. The module of claim 1, wherein the light-emitting device has a beam angle of 140° or more when emitting light from a side surface of the light-emitting device.

5. The module of claim 1, wherein the siloxane-based compound comprises a substituent represented by Chemical Formula 1: 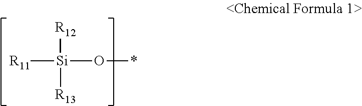
wherein, in Chemical Formula 1,
R₁₁ to R₁₃ are each independently selected from the group consisting of hydrogen, a C₁ to C₂₀ alkyl group, and a C₂ to C₂₀ alkenyl group, and at least one of R₁₁ to R₁₃ is a C₂ to C₂₀ alkenyl group.

6. The module of claim 1, wherein the siloxane-based compound comprises a siloxane-based compound represented by Chemical Formula 1-1 below: 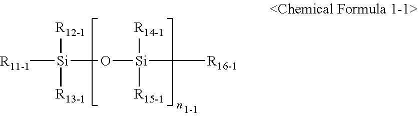
wherein, in Chemical Formula 1-1,
R₁₁₋₁ to R₁₃₋₁ are each independently selected from the group consisting of hydrogen, a C₁ to C₂₀ alkyl group, and a C₂ to C₂₀ alkenyl group, and at least one of R₁₁₋₁ to R₁₃₋₁ is a C₂ to C₂₀ alkenyl group,
R₁₄₋₁ and R₁₅₋₁ are each independently selected from the group consisting of hydrogen and a C₁ to C₂₀ alkyl group,
R₁₆₋₁ is selected from the group consisting of hydrogen, a C₁ to C₂₀ alkyl group, and a C₂ to C₂₀ alkenyl group, and
n₁₋₁ is 100 to 500.

7. The module of claim 1, wherein the siloxane-based compound comprises a siloxane-based compound represented by Chemical Formula 1-2 below: 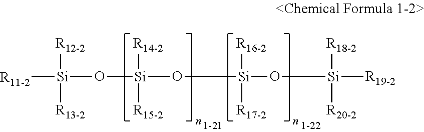
wherein, in Chemical Formula 1-2,
R₁₁₋₂ to R₁₃₋₂ are each independently selected from the group consisting of hydrogen, C₁ to C₂₀ alkyl group, and a C₂ to C₂₀ alkenyl group, and at least one of R₁₁₋₂ to R₁₃₋₂ is a C₂ to C₂₀ alkenyl group,
R₁₄₋₂ to R₁₇₋₂ are each independently selected from the group consisting of hydrogen, a C₁ to C₂₀ alkyl group, and a C₂ to C₂₀ alkenyl group, and at least one of R₁₄₋₂ to R₁₇₋₂ is a C₂ to C₂₀ alkenyl group,
R₁₈₋₂ to R₂₀₋₂ are each independently selected from the group consisting of hydrogen, a C₁ to C₂₀ alkyl group, and a C₂ to C₂₀ alkenyl group, and
n₁₋₂₁ and n₁₋₂₂ are 100 to 500.

8. The module of claim 1, wherein the siloxane-based compound comprises a siloxane-based compound represented by Chemical Formula 1-3 below: 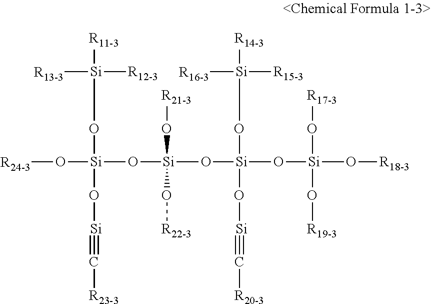
wherein, in Chemical Formula 1-3,
R₁₁₋₃ to R₁₃₋₃ are each independently selected from the group consisting of hydrogen, a C₁ to C₂₀ alkyl group, and a C₂ to C₂₀ alkenyl group, and at least one of R₁₁₋₃ to R₁₃₋₃ is a C₂ to C₂₀ alkenyl group, and
R₁₄₋₃ to R₂₄₋₃ are each independently selected from the group consisting of hydrogen, a C₁ to C₂₀ alkyl group, and a C₂ to C₂₀ alkenyl group.

9. The module of claim 6, wherein the siloxane-based compound represented by Chemical Formula 1-1 is a siloxane-based compound represented by Chemical Formula 1-1-1 below: 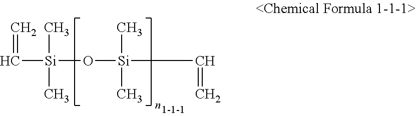
wherein, in Chemical Formula 1-1-1,
n₁₋₁₋₁ is 100 to 500.

10. The module of claim 7, wherein the siloxane-based compound represented by Chemical Formula 1-2 is a siloxane-based compound represented by Chemical Formula 1-2-1 below: 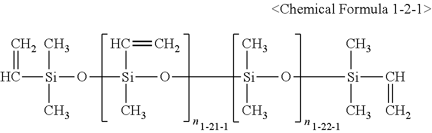
wherein, in Chemical Formula 1-2-1,
n₁₋₂₁₋₁ and n₁₋₂₂₋₁ are each independently 100 to 500.

11. The module of claim 8, wherein the siloxane-based compound represented by Chemical Formula 1-3 is a siloxane-based compound represented by Chemical Formula 1-3-1 below:

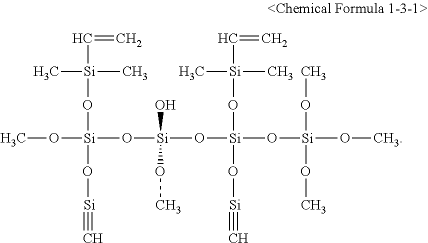

12. The module of claim 1, wherein the base resin comprises at least two or more siloxane-based compound selected from the group consisting of a siloxane-based compound represented by Chemical Formula 1-1 below, a siloxane-based compound represented by Chemical Formula 1-2 below, and a siloxane-based compound represented by Chemical Formula 1-3 below: 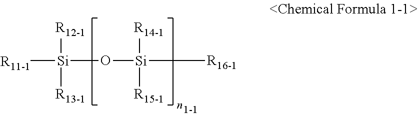
wherein, in Chemical Formula 1-1,
R₁₁₋₁ to R₁₃₋₁ are each independently selected from the group consisting of hydrogen, a C₁ to C₂₀ alkyl group, and a C₂ to C₂₀ alkenyl group, and at least one of R₁₁₋₁ to R₁₃₋₁ is a C₂ to C₂₀ alkenyl group,
R₁₄₋₁ and R₁₅₋₁ are each independently selected from the group consisting of hydrogen and a C₁ to C₂₀ alkyl group,
R₁₆₋₁ is hydrogen, a C₁ to C₂₀ alkyl group, or a C₂ to C₂₀ alkenyl group, and
n₁₋₁ is 100 to 500; 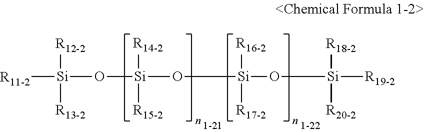
wherein, in Chemical Formula 1-2,
R₁₁₋₂ to R₁₃₋₂ are each independently selected from the group consisting of hydrogen, C₁ to C₂₀ alkyl group, and a C₂ to C₂₀ alkenyl group, and at least one of R₁₁₋₂ to R₁₃₋₂ is a C₂ to C₂₀ alkenyl group,
R₁₄₋₂ to R₁₇₋₂ are each independently selected from the group consisting of hydrogen, a C₁ to C₂₀ alkyl group, and a C₂ to C₂₀ alkenyl group, and at least one of R₁₄₋₂ to R₁₇₋₂ is a C₂ to C₂₀ alkenyl group,
R₁₈₋₂ to R₂₀₋₂ are each independently selected from the group consisting of hydrogen, a C₁ to C₂₀ alkyl group, and a C₂ to C₂₀ alkenyl group, and
n₁₋₂₁ and n₁₋₂₂ are 100 to 500; 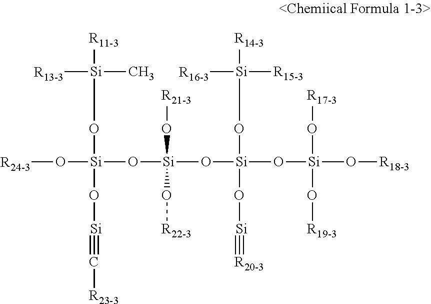
wherein, in Chemical Formula 1-3,
R₁₁₋₃ to R₁₃₋₃ are each independently selected from the group consisting of hydrogen, a C₁ to C₂₀ alkyl group, and a C₂ to C₂₀ alkenyl group, and at least one of R₁₁₋₃ to R₁₃₋₃ is a C₂ to C₂₀ alkenyl group, and
R₁₄₋₃ to R₂₄₋₃ are each independently selected from the group consisting of hydrogen, a C₁ to C₂₀ alkyl group, and a C₂ to C₂₀ alkenyl group.

13. The module of claim 12, wherein the base resin comprises:
70.0 to 90.0 wt % of the siloxane-based compound represented by Chemical Formula 1-1;
1.0 to 20.0 wt % of the siloxane-based compound represented by Chemical Formula 1-2; and
5.0 to 25.0 wt % of the siloxane-based compound represented by Chemical Formula 1-3.

14. The module of claim 1, wherein the base resin comprises a siloxane-based compound represented by Chemical Formula 2 below: 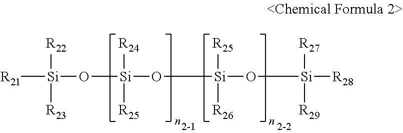
wherein, in Chemical Formula 2,
R₂₁ to R₂₉ are each independently selected from the group consisting of hydrogen and a C₁ to C₂₀ alkyl group, and
n₂₋₁ and n₂₋₂ are each independently 1 to 100.

15. The module of claim 14, wherein the siloxane-based compound represented by Chemical Formula 2 is a siloxane-based compound represented by Chemical Formula 2-1 below: 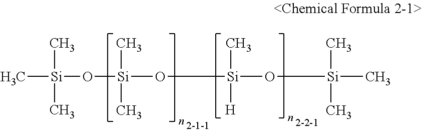
wherein, in Chemical Formula 2-1,
n₂₋₁₋₁ and n₂₋₂₋₁ are each independently 1 to 100.

16. The module of claim 14, wherein the base resin comprises 1.0 to 26.0 wt % of the siloxane-based compound represented by Chemical Formula 2.

17. The module of claim 1, wherein the (meth)acrylic diffusion agent comprises one or more selected from the group consisting of polyalkyl (meth)acrylate; polyalkyl (meth)acrylate-co-polystyrene; a mixture of polyalkyl (meth)acrylate and polycarbonate; a mixture of polyalkyl (meth)acrylate and silica; and a mixture of polyalkyl (meth)acrylate and polyoxymethylene.

18. The module of claim 17, wherein the polyalkyl (meth)acrylate is polymethylmethacrylate.

19. The module of claim 1, wherein the (meth)acrylic diffusion agent has an average particle size of 0.5 to 5.0 μm.

20. The module of claim 1, wherein the (meth)acrylic diffusion agent has a refractive index of 1.450 to 1.540.
